(19) United States
(12) Patent Application Publication
(10) Pub. No.: US 2010/0032766 A1
(43) Pub. Date: Feb. 11, 2010

(54) Bipolar Junction Transistor with a Reduced Collector-Substrate Capacitance

(75) Inventors: Alan Sangone Chen, Windermere, FL (US); Mark Victor Dyson, Singapore (SG); Edward Belden Harris, Fogelsville, PA (US); Daniel Charles Kerr, Oak Ridge, NC (US); William John Nagy, Catasauqua, PA (US)

Correspondence Address: AGERE;LERNER, DAVID et al., 600 SOUTH AVENUE WEST, WESTFIELD, NJ, 07090, US

(73) Assignee: Agere Systems Inc., Allentown, PA (US)

(21) Appl. No.: 12/308,158

(22) PCT Filed: Jun. 2, 2006
(86) PCT No.: PCT/US2006/021396

§ 371 Date: Oct. 13, 2009

(51) Int. Cl. H01L 27/102; H01L 21/331; H01L 21/8249; H01L 29/73

(52) U.S. Cl. 257/370; 438/353; 438/234; 257/565; 257/E21.37; 257/E21.696; 257/E29.174; 257/E27.074

(57) ABSTRACT

A process for forming a bipolar junction transistor (BJT) in a semiconductor substrate and a BJT formed according to the process. A buried isolation region is formed underlying BJT structures to isolate the BJT structures from the p-type semi-conductor substrate. To reduce capacitance between a BJT subcollector and the buried isolation region, prior to implanting the subcollector spaced-apart structures are formed on a surface of the substrate. The subcollector is formed by implanting ions through the spaced-apart structures and through a region intermediate the spaced-apart structures. The formed BJT subcollector therefore comprises a body portion and end portions extending therefrom, with the end portions disposed at a shallower depth than the body portion, since the ions implanting the end portions must pass through the spaced-apart structures. The shallower depth of the end portions reduces the capacitance.

### FIELD OF THE INVENTION

The invention relates generally to integrated circuit fabrication processes and structures formed according to the processes, and more specifically to fabrication processes for forming a vertical PNP transistor with reduced collector-substrate capacitance and vertical PNP transistors formed according to the process.

### BACKGROUND OF THE INVENTION

A plurality of integrated circuits are formed on a semiconductor wafer according to a sequence of process steps, collectively referred to as a wafer fabrication process. Each integrated circuit comprises a semiconductor substrate and semiconductor devices, such as transistors (e.g., bipolar junction transistors (BJTs) and metal-oxide semiconductor field effect transistors (MOSFETs)) formed from doped regions within the substrate. Interconnect structures overlie the semiconductor substrate for electrically connecting the doped regions to form electrical devices and circuits implementing desired electrical functions. Conventional interconnect structures comprise substantially horizontal dielectric layers separating overlying and underlying substantially horizontal conductive structures comprising conductive traces or runners. Vertical conductive vias or plugs in the dielectric layers connect the horizontal conductive structures in the overlying and underlying conductive layers. The various layers and regions are formed and patterned using conventional fabrication techniques, such as oxidation, implantation, deposition, epitaxial growth, lithography, developing, etching, and planarization.

The sequence of process steps must be carefully designed and executed to ensure that the devices are properly formed and that processes associated with later steps do not adversely affect previously-formed structures, as such adverse effects can impair device operation, lowering fabrication yields and increasing costs. It is also desired to limit the number of mask steps to lower fabrication costs. Thus semiconductor manufactures desire to implement a fabrication process flow that produces properly operable transistors (e.g., PNP and NPN BJTs and MOSFETs) and other devices with a high fabrication yield.

A BJT comprises three adjacent doped semiconductor regions or layers having an NPN or a PNP doping configuration. A middle region forms a base and two end regions form an emitter and a collector. Typically, the emitter has a higher dopant concentration than the base and the collector, and the base has a higher dopant concentration than the collector. Generally, the BJT can be operated as an amplifier (for example, to amplify an input signal supplied between the base and the emitter, with the output signal appearing across the emitter/collector) or as a switch (for example, an input signal applied across the base/emitter switches the emitter/collector circuit to an opened or a closed state.

A MOSFET, which differs in structure and operation from a BJT, comprises source and drain regions of a first dopant type formed in a tub or well of a second dopant type. A voltage applied to a gate disposed above the well between the source and drain changes a conductivity of a channel region between the source and the drain, permitting current flow through the channel.

BiCMOS integrated circuits comprise both BJTs and CMOS (complementary MOSFETs, i.e., a p-type MOSFET (PMOSFET) and an n-type MOSFET (NMOSFET)) formed on the same substrate with the fabrication process steps for both devices integrated into one fabrication sequence. BiCMOS circuits have many uses in the electronics industry, combining the high power and fast switching speeds of bipolar devices with the high density and low power consumption of MOSFETS. The multitude of applications for BiCMOS devices has encouraged the development of faster and denser BiCMOS integrated circuits with higher current capacity.

There are several known semiconductor fabrication processes for forming the three doped layers of a BJT and several transistor architectures can be formed according to such processes. The fabrication of NPN BJTs is typically optimized for a given process and the PNP BJTs can be “free,” i.e., certain masks are modified to form PNP BJT structures, but no additional process steps are required. A lateral BJT structure, where the current flows laterally from the emitter to the collector is one type of “free” PNP BJT.

A common vertical BJT planar structure (where the current flows perpendicular to a plane of the substrate) comprises stacked NPN or PNP regions formed by successive dopant implants into a substrate. Significant performance enhancements are achieved by forming the emitter from a polysilicon layer. For example, using a polysilicon emitter allows greater control over the emitter-base doping profile. Further performance enhancements are achieved by using two layers of polysilicon (referred to as a double-polysilicon BJT) one polysilicon layer for the emitter and the other for an extrinsic base. This architecture reduces base resistance and collector-base capacitance, among other advantages.

In one embodiment the PNP BJT is fabricated on a p-type substrate, requiring the use of an n-type layer in the substrate to isolate the p-type substrate from the BJT p-type collector. A parasitic capacitance is formed across the reverse-biased junction between the collector and the isolating structure, referred to as a collector-substrate capacitance or a collector-n-isolation region capacitance Ccs. As is known, this capacitance degrades high-frequency BJT performance in analog applications and lowers BJT switching speed in digital applications.

A cross-sectional illustration of such a prior art vertical PNP BJT 600 is illustrated in FIG. 10. The vertical PNP BJT 600 can be used, for example, in a preamplifier application. FIG. 10 illustrates half of the regions comprising the PNP BJT 600, symmetric about a line of symmetry 606.

Doped regions of the PNP BJT 600 are formed within a substrate 608 and isolated by isolation regions 610. An n-type isolation sinker region 611 cooperates with an n-type isolation triple well region 612 to form a triple well isolation structure.

A collector region is indicated generally by a reference character 615, including a highly-doped collector contact surface region 614 within a p-type sinker 618. Since a subcollector region 620 is deep within the substrate 608 (in an embodiment having a high breakdown voltage the subcollector region can be more than 1 micron below an upper surface of the substrate) the collector contact surface region 614 cannot make satisfactory contact with the subcollector region 620, necessitating use of the p-type sinker 618. The collector 615 may also include an optional p-type SIC (selectively implanted collector) region 622.

A polysilicon emitter 624 overlies and is separated from an n-type intrinsic base 626 by a dielectric material layer 627. Transistor action occurs at the junction between the intrinsic base and the emitter. The intrinsic base 626 contacts an n-type extrinsic base 628, a heavily-doped region that links the intrinsic base 626 to later formed conductive plugs (base contacts) in electrical communication with the extrinsic base 628.

An n-type isolation contact surface region 634 within the n-type sinker region 611 is biased to isolate the PNP collector regions from the p-type substrate 608.

Contact to the emitter 604 is made on a top surface of the emitter polysilicon 604 and contact to the collector is made through the collector contact surface region 614.

The doped regions and contacts of the PNP BJT 600 are fabricated according to known fabrication processes.

The collector-n-isolation region parasitic capacitance Ccs between the subcollector region 620 and the isolation region 612 is illustrated in phantom in FIG. 10. A peripheral or sidewall parasitic capacitance Cs formed between the p-type sinker 618 and the n-type sinker region 611 is also illustrated. As is known, both parasitic capacitances are directly related to the area of the reverse biased junction and the dielectric constant of the material, and inversely related to the width of the reverse-biased junctions across which the capacitance is formed. Both parasitic capacitance degrade high-speed performance of the BJT.

The sidewall capacitance can be reduced by employing deep trench isolation in which a deep trench (not shown in FIG. 10) is formed between the sinker regions 611 and 618. The trench is filled with silicon dioxide. The sidewall capacitance is reduced because the dielectric constant of the silicon dioxide is about one fourth the dielectric constant of the silicon between the sinker region 618 and the substrate 608 when the deep trench is not present. This technique does not affect the collector-n-isolation region capacitance.

In yet another prior art PNP BJT the isolation triple well region is implanted, an epitaxial layer is grown over the isolation region and the collector is implanted in the epitaxial layer. This process controls the collector depth to reduce the distance between the collector and the underlying isolation region, reducing the capacitance between these two structures. Disadvantageously, this process requires two implant steps and the epitaxial growth step tends to introduce defects into the grown silicon.

In another PNP BJT embodiment (not illustrated) the collector is formed proximate a buried silicon dioxide layer (e.g., a silicon-on-insulator layer) to reduce the collector-n-isolation region parasitic capacitance. Use of both the buried oxide layer and the deep oxide trenches provides the lowest capacitance values for Ccs and Cs.

In yet another alternative, an n-type substrate is substituted for the p-type substrate, i.e. the PNP BJT is formed in an n-type substrate. Although this approach reduces the PNP BJT collector-isolation region parasitic capacitance by eliminating the n-isolation region, (the revere biased pn junction between the p-type collector and the n-type substrate provides suitable isolation). In an application where an NPN BJT is also fabricated on the substrate (a typical configuration), the problems associated with the parasitic capacitance are merely shifted from the PNP BJT to the NPN BJT. Further, a p-type substrate is generally preferred for BiCMOS circuits in which MOSFETs and BJTs are formed.

It is therefore desired to identify process techniques and structures that further reduce the collector-n-isolation region capacitance Ccs.

### BRIEF SUMMARY OF THE INVENTION

According to one embodiment, the present invention comprises a method for forming a bipolar junction transistor. The method comprises providing a semiconductor layer having a surface, forming spaced-apart first and second collector regions in the semiconductor layer, forming a buried isolation region below a lower surface of the first and the second collector regions and implanting a subcollector comprising first and second end portions extending from a body portion, the first and the second end portions overlapping the respective first and second collector regions, wherein the first and the second end portions are shallower, relative to the surface, than the body portion.

According to another embodiment of the invention, a bipolar junction transistor comprises a semiconductor substrate having a surface, spaced apart first and second collector regions in the substrate and a third collector region having a body portion and first and second end portions extending therefrom, the first and second end portions overlapping the respective first and second collector regions, wherein the first and second end portions are shallower relative to the surface than the body portion.

### BRIEF DESCRIPTION OF THE DRAWINGS

The present invention can be more easily understood and the advantages and uses thereof more readily apparent when the following detailed description of the present invention is read in conjunction with the figures wherein:

FIGS. 1-4 are cross-sectional views of structures formed across a common plane according to sequential processing steps of the present invention to form a first PNP BJT.

FIGS. 5A and 5B illustrate PNP BJT doping profiles according to the prior art and according to the teachings of the present invention, respectively.

FIG. 6 illustrates dimensions for one embodiment of certain structures of the PNP BJT of FIG. 1 as determined according to the teachings of the present invention.

FIG. 7 is a cross-sectional view of a second PNP BJT constructed according to the teachings of the present invention.

FIG. 8 is a cross-sectional view of an NPN BJT constructed according to the teachings of the present invention.

FIG. 9 is a cross-sectional view of a BiCMOS integrated circuit comprising a PNP BJT constructed according to the teachings of the present invention.

FIG. 10 is a cross-sectional view of prior art PNP BJT.

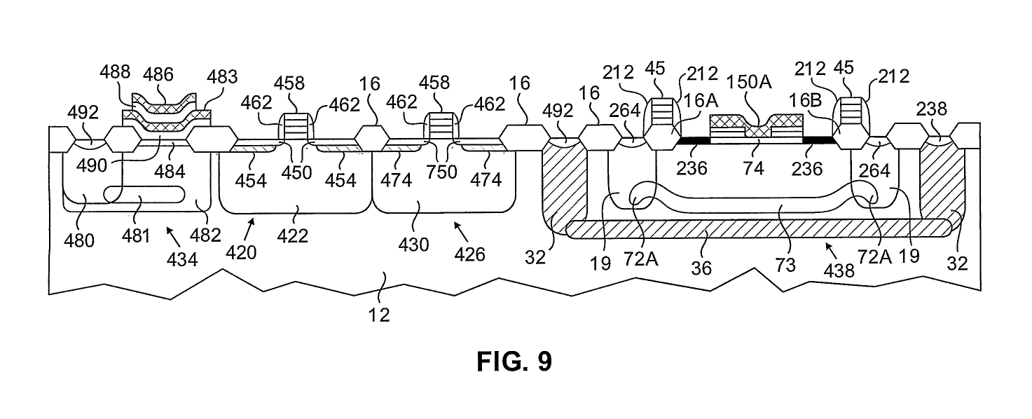

In accordance with common practice, the various described features are not drawn to scale, but are drawn to emphasize specific features relevant to the invention. Like reference characters denote like elements throughout the figures and text.

### DETAILED DESCRIPTION OF THE INVENTION

Before describing in detail exemplary methods and apparatuses related to fabrication of a vertical PNP BJT in a BiCMOS process and structures formed according to the process to reduce the parasitic collector-n-isolation region capacitance, it should be observed that the present invention resides primarily in a novel and non-obvious combination of elements and process steps. So as not to obscure the disclosure with details that will be readily apparent to those skilled in the art, certain conventional elements and steps have been presented with lesser detail, while the drawings and the specification describe in greater detail other elements and steps pertinent to understanding the invention. The illustrated process steps are exemplary, as one skilled in the art recognizes that certain independent steps illustrated below may be combined and certain, steps may be separated into individual sub-steps to accommodate individual process variations.

The teachings of the present invention are applicable to silicon PNP and NPN BJTs and to heterojunction bipolar junction transistors (HBTs), wherein the three material regions of the BJTs and the HBTs comprise silicon, silicon-germanium, gallium-arsenide or other suitable materials. The description below refers to an exemplary silicon PNP BJT to describe the invention.

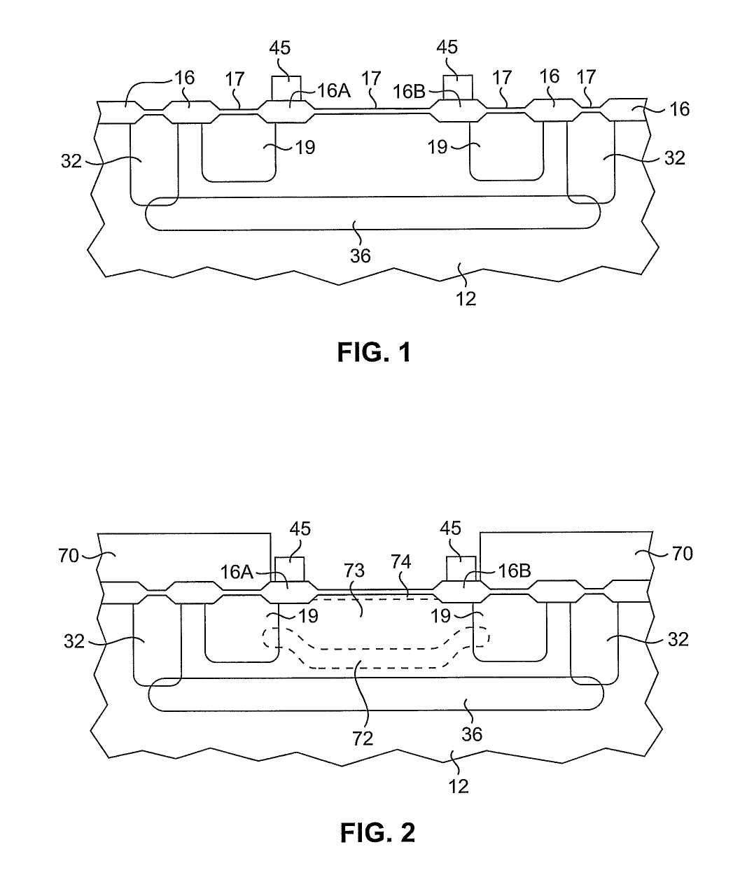

A vertical PNP may be fabricated as follows with reference to the process sequence depicted in FIGS. 1-4 illustrating cross-sectional views of formed structures according to a sequence of exemplary fabrication steps. The details of individual processing steps referred to herein are known in the art and need not be described in detail. The process sequence is adaptable to a BiCMOS process for forming an NMOSFET and a PMOSFET (functioning as a CMOS pair) and a PNP BJT. The teachings are also applicable to a process sequence for forming a CMOS pair, a NPN BJT and a PNP BJT on a semiconductor substrate.

Structural elements as illustrated in FIG. 1 are formed in a semiconductor substrate 12 according to known fabrication techniques, such as oxidation, implantation, deposition, diffusion, epitaxial growth, lithography, developing, etching, and planarization. As will be seen from the further description below, the isolation structures 16 isolate an emitter, a base and a collector of the PNP BJT. Silicon dioxide regions 17 span a region between adjacent isolation structures 16.

P-type dopants implanted through a suitably patterned photoresist structure form p-type sinker regions 19. N-type dopants implanted through a suitably patterned photoresist structure form n-type sinker isolation regions 32. An n-type triple well isolation region 36 is formed by implanting n-type dopants through an appropriately patterned photoresist structure. Exemplary implant conditions for forming the triple well isolation region 36 comprise phosphorous implanted at 1200 keV with a density of 4E12 per cm³. Spaced-apart lateral ends 36A of the n-type triple well isolation region 36 overlap with lower ends of the n-type sinker isolation regions 32 to form an n-type triple well isolation tub surrounding the p-type sinker regions 19 and other later-formed PNP BJT structures.

Structures 45 overlying isolation structures 16A and 16B are formed by depositing and patterning one or more material layers. In an embodiment where MOSFETS are formed in the substrate 12, the structures 45 can each comprise a MOSFET gate stack. Other suitable materials (including dielectric materials) may be used to form the structures 45. The gate stacks are formed by blanket depositing a gate oxide layer, polysilicon layer (doped in situ or by implant doping) and a tungsten layer. The polysilicon and tungsten layers ate etched according to a pattern in an overlying patterned photoresist layer or, more commonly in an overlying hard mask layer. In the latter case, each gate stack comprises a polysilicon layer, a tungsten silicide layer (formed from the polysilicon and tungsten) and a hard mask layer. In one embodiment the gate stacks, and thus the structures 45, are about 300 nm thick.

Through a patterned photoresist structure 70 (see FIG. 2), a high-energy p-type implant forms a PNP BJT subcollector 72 (overlapping the p-type sinker regions 19) and a collector 73. One exemplary subcollector implant condition uses boron at about 1200 keV and a dose of about 6E13 per cm³.

The structures 45 overlying the isolation structures 16A and 16B reduce the implant range of the implanted subcollector 72 over portions of the subcollector 72 underlying the structures 45, forming end regions 72A overlapping the p-type sinker regions 19 and spaced vertically apart from the n-type triple well isolation region 36. The implant range is reduced by a distance about equal to a thickness of the structures 45.

This spaced-apart end regions 72A in the subcollector 72 reduce the collector-n-isolation region capacitance since the capacitance is inversely proportional to the distance between the charged regions of the reverse biased junction formed between the p-type collector and the n-type isolation region. This feature also reduces the collector resistance because the subcollector end regions 72A are each closer to a respective collector contact surface region formed later in a surface of the sinker regions 19.

Continuing with FIG. 2, a low energy n-type implant forms a PNP BJT base 74.

The teachings of the present invention can be applied to the formation of a PNP BJT in various types of integrated circuits, including a BiCMOS integrated circuit including both BJTs and MOSFETs. In this application, a spacer oxide layer is formed over a substrate surface to form spacers adjacent the MOSFETs gate stacks. Such a spacer oxide layer 82 is illustrated in FIG. 3. A PNP emitter window is formed in the spacer oxide layer 82 and an underlying screen oxide layer 54 by etching through an opening in a patterned photoresist structure. An optional SIC implant can be made through the window to form a selectively implanted collector region (not shown). After cleaning the substrate, a polysilicon layer 150 is deposited over the upper surface of the substrate 12 and within the emitter window as illustrated in FIG. 3. Boron or another p-type dopant is implanted into the polysilicon layer 150 or the layer is doped in situ.

According to an appropriately patterned mask, the polysilicon layer 150 is etched to form a PNP emitter 150A. See FIG. 4. The spacer oxide layer 82 is etched to form gate stack spacers for the MOSFETS (not illustrated) and spacer regions 212 laterally adjacent the structures 45.

N+ extrinsic base regions 236 are formed in spaced-apart end regions of the base 74 by implant doping through a patterned mask. N+ high-dopant density contact surface regions 238 are formed in the sinker isolation regions 32.

Using a patterned implant mask, high-dopant density collector surface regions 264 are formed in a surface of the PNP collector regions 19 as illustrated in FIG. 4.

An edge 270 of each one of the structures 45 is preferably located to avoid overlap with the extrinsic base regions 236 (as any overlap can detrimentally affect the implant doping that forms the extrinsic base regions 236) and also to maintain a suitable base-collector breakdown voltage, i.e., avoid reducing a distance between the subcollector 72 and the base 74 that lowers the base-collector breakdown voltage. A width of the structures 45 must also consider a width of the underlying isolation structures 16A and 16B.

An edge 280 of each one of the structures 45 is preferably located within an opening of a subcollector mask through which the subcollector 72 is formed, ensuring that a distance between the subcollector 72 and the n-isolation region 36 is greater at the end portions 72A than at other regions of the subcollector 72.

A silicon dioxide layer (not shown) is formed (typically according to a high-density plasma deposition process) to encapsulate the substrate 12 and the structures formed therein to prevent the dopant atoms from evaporating from the semiconductor material during a subsequent anneal process. The substrate 12 is annealed to repair crystal lattice damage resulting from collisions between the implanted n-type and p-type dopants and the lattice atoms and to electrically activate the implanted dopants.

Conventional processing steps (referred to as backend process steps) are performed to passivate the upper surface of the substrate 12, fabricate interconnect structures and package the device. A first dielectric layer and a first conductive layer are deposited overlying the substrate 12 to form a first layer interconnect (not shown in the Figures). The first level interconnect structures comprise conductive plugs formed in the dielectric layer for contacting the PNP emitter 150B, the PNP extrinsic bases 236, the high-dopant density contact surface regions 238 in the sinker isolation regions 32 and the PNP high-dopant density collector contact surface regions 264.

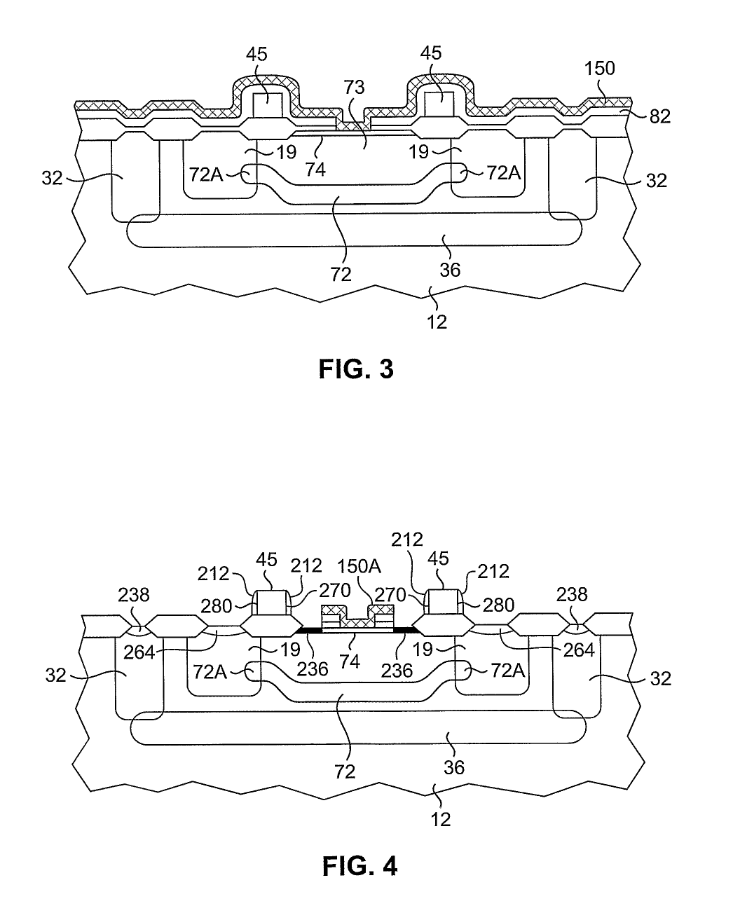

FIGS. 5A and 5B illustrate region doping profiles for a PNP BJT of the prior art (FIG. 5A) and for a PNP BJT fabricated according to the present invention (FIG. 5B). As can be seen, the subcollector doping profile is shifted toward the surface of the semiconductor layer by the about 0.3 um, which is the approximate thickness of the structures 45. The doping profile of the n-type isolation region (i.e., the triple well 36) remains unchanged between the two Figures since it is formed prior to formation of the inventive structures 45. The increased separation of the highly doped regions of the subcollector and the n-type isolation region reduces the collector-n-isolation region junction capacitance.

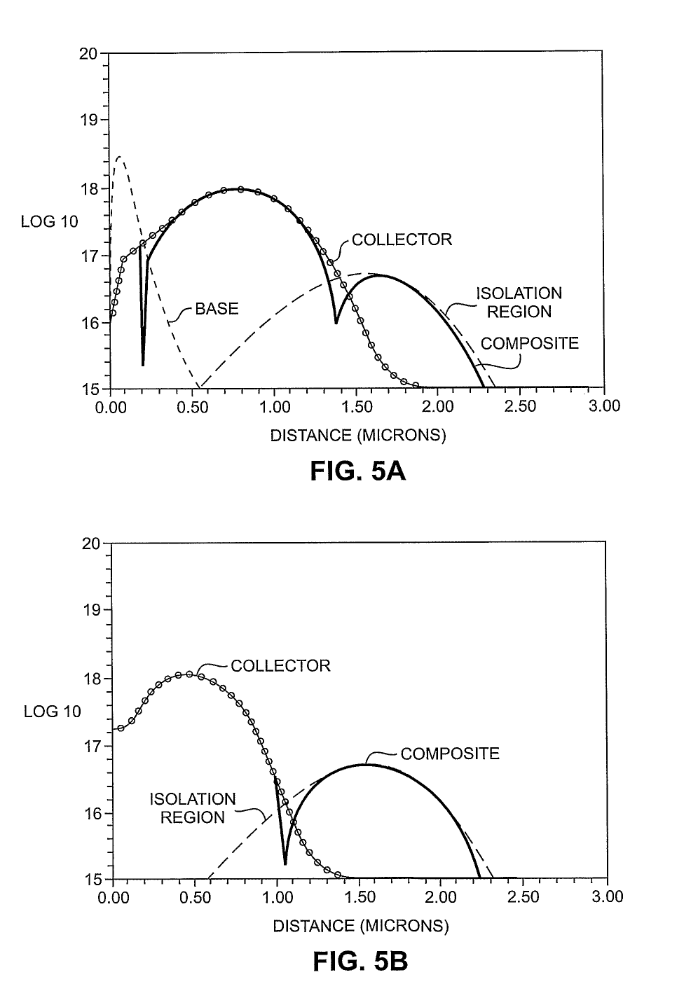

FIG. 6 illustrates approximate dimensions for certain structures formed according to one embodiment of the present invention. The implant range for the dopants implanted to form the subcollector 72 is affected (about one-for-one) by the height of the structures 45 above an upper surface 12A of the substrate 12. As can be seen, the structure 45 is about 0.3 μm thick, raising the deposition depth of the end regions 72A about 0.4 μm above the subcollector 72. The additional 0.1 μm is contributed by an upper region of the isolation structure 16 that is about 0.1 μm above the upper surface 12A. This figure comports with the doping profiles illustrated in FIG. 5B as described above.

Use of the structures 45 also ensures that the base implant (i.e., the base 74 implanted as described in conjunction with FIG. 2) does not extend to a region below the isolation structures 16A and 16B. Preferably, the base should be implanted in the surface of the substrate 12 between the isolation structures 16A and 16B, i.e., to contact the emitter region 150B and the extrinsic base regions 236 (see FIG. 4). If the base implants extend below the isolation structures 16A and 16B, i.e., in a direction toward the collector contacts 264 of FIG. 4, a base-collector capacitance increases responsive to the decreased distance between the base and the collector regions 19. The structures 45 overlying the isolation structures 16A and 16B cause the implanting dopants to lose energy as they travel through these structures. The reduced dopant energy shifts the implanted base upwardly, ensuring that the base implant does not dope regions below the isolation structures 16A and 16V and increase the base-collector capacitance. The spacers 212 further expand the design space for the base 74, allowing the base implant with heavier implanting ions, since the spacers 212 will also prevent those ions from reaching the substrate 12 below the isolation structures 16A and 16B.

In an embodiment where the structures 45 comprise MOSFET gate stacks, the polysilicon material layer in the gate stack can be connected to ground, forming a shield or field plate to limit cross talk or electrical interference between devices.

The process according to the present invention for decreasing the capacitance between the PNP collector and the n-isolation region is easily adaptable to current fabrication process flows as no additional processing steps are required. Only different mask configurations are required. For example, although described with reference to a PNP BJT emitter formed from a polysilicon layer and an implanted base, the teachings of the present invention can also be applied to a PNP BJT comprising an extrinsic base and an emitter each formed from separate polysilicon layers, and can be applied to a PNP BJT comprising an implanted emitter and an implanted base.

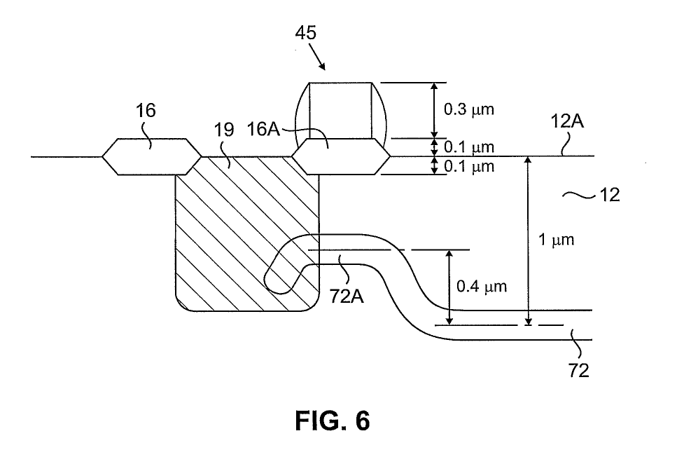

While the process of the invention has been described with reference to a PNP BJT having a single polysilicon emitter region (150B) intermediate extrinsic base regions (236), the teachings of the present invention can also be applied to a BJT having two spaced-apart emitter regions with a base region intermediate thereto as further described and claimed in commonly owned patent application entitled Processes for Forming Bipolar Junction Transistors and Bipolar Junction Transistors Formed According to the Processes, (attorney docket number Chen 21-1-15-7-9/075903-464) filed on ______ and assigned application number ______, the teachings of which are herein incorporated by reference. FIG. 7 illustrates a PNP BJT comprising emitter regions 300A and 300B with an extrinsic base region 302 intermediate the emitter regions.

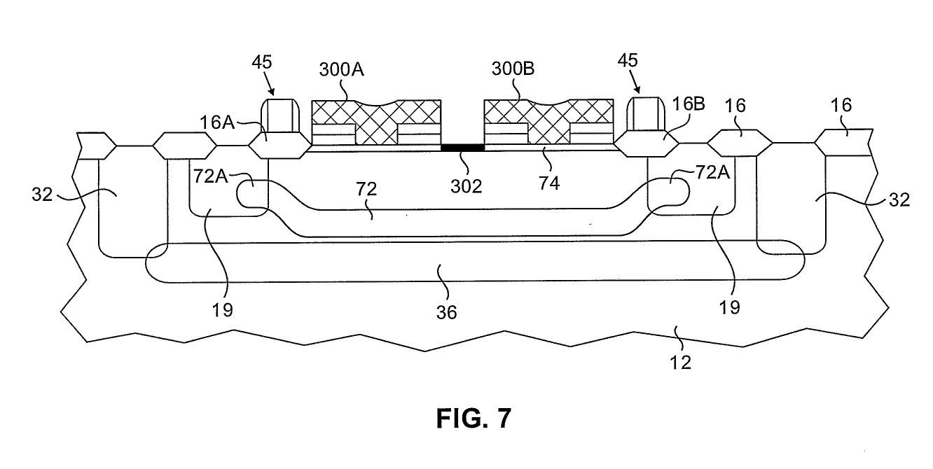

The process of the present invention can also be applied to the fabrication of an NPN BJT in an n-type substrate for reducing capacitance between the NPN BJT collector and the underlying p-type isolation region and the fabrication of an NPN BJT in an n-type well formed in a p-type substrate. An NPN BJT 360 of FIG. 8 formed in an n-type well 362, which is formed in a p-type substrate 364, comprises p-type isolation sinker regions 368 cooperating with a p-type triple well isolation region 372 to form a triple well isolation tub surrounding the structures of the NPN BJT 360. Collector sinker regions 380 overlap end portions 384A of a subcollector 384. The end portions 384A are shallower than other regions of the subcollector 384 due to the implant range-reduction effects of structures 388 overlying isolation regions 16A and 16B. The NPN BJT further comprises a base 390 and an emitter 392. A high-dopant density contact surface region 396 is disposed in each collector sinker region 380 and a high-dopant density contact surface region 400 is disposed in each isolation sinker region 368 for connecting these regions, through conductive vias in contact with the high-dopant density contact surface regions, to other devices formed in the substrate 364.

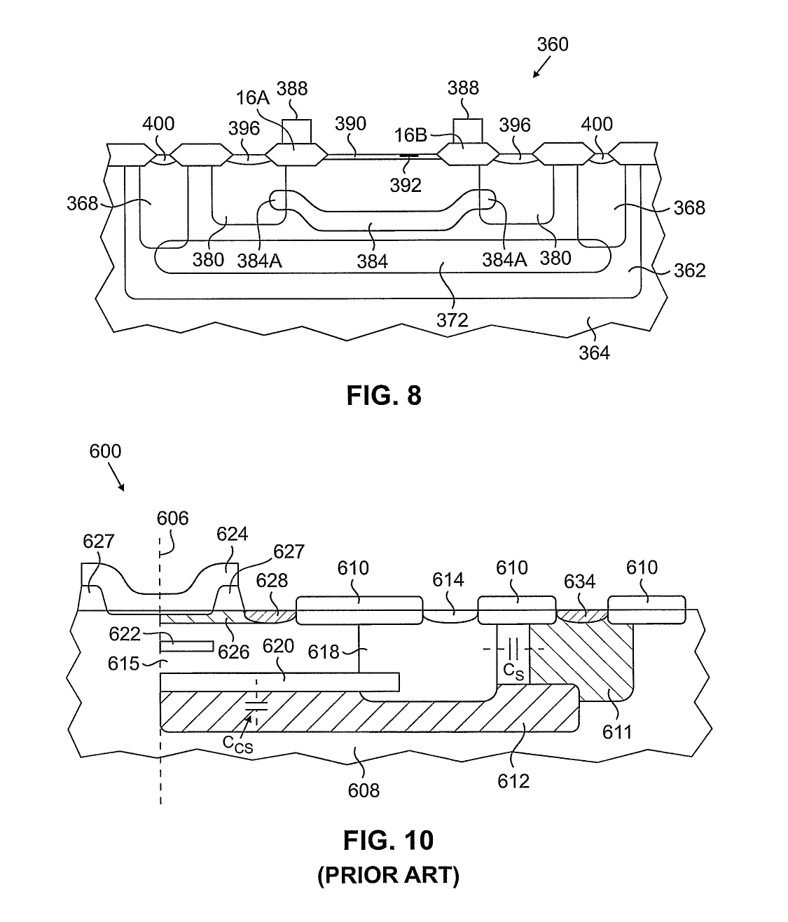

The process for forming the PNP transistor of the present invention can also be applied to a complementary BiCMOS process and structures formed according to the process. Generally, it will be appreciated that one can fabricate the novel device independently of its application to any specific process or in conjunction with the fabrication of other devices in the substrate. FIG. 9 illustrates an NMOSFET 420 formed in a p-tub 422, a PMOSFET 426 formed in an n-tub 430, a NPN BJT 434 and a PNP BJT 438, the latter constructed according to the teachings of the present invention as described in conjunction with FIGS. 1-4. The NMOSFET 420 further comprises lightly-doped regions 450, source/drain regions 454, a gate stack 458 and sidewall spacers 462. The PMOSFET 426 further comprises lightly-doped regions 470, source/drain regions 474, the gate stack 458 and the sidewall spacers 462. The NPN BJT comprises a collector sinker region 480 and an overlapping subcollector 481, both in an n-tub 482, an extrinsic base polysilicon structure 483, an intrinsic base 484, an emitter polysilicon structure 486, intermediate dielectric material layers 488 and 490 and a high dopant-density collector contact surface region 492. In this embodiment, the structures 45 comprise MOSFET gate stacks formed simultaneously with the NMOSFET and PMOSFET gate stacks 458.

It should also be recognized that while the embodiment described utilizes compounds or elements commonly employed in today's technology as dopants, isolation layers and the like, it is possible to substitute other materials that function in the same manner for the preferred materials of today's technology.

Although the present invention has been described with reference to preferred embodiments, it will be understood by those skilled in the art that various changes may be made and equivalent elements may be substituted for the elements thereof without departing from the scope of the invention. The scope of the present invention further includes any combination of elements from the various embodiments set forth herein. In addition, modifications may be made to adapt a particular situation to the teachings of the present invention without departing from its essential scope. Therefore, it is intended that the invention not be limited to the particular embodiments disclosed, but that the invention will include all embodiments failing within the scope of the appended claims.

What is claimed is:

1. A method for forming a bipolar junction transistor, comprising:
providing a semiconductor layer having a surface;
forming spaced-apart first and second collector regions in the semiconductor layer; forming a buried isolation region below a lower surface of the first and the second collector regions;
implanting a subcollector comprising first and second end portions extending from a body portion, the first and the second end portions overlapping the respective first and second collector regions, wherein the first and the second end portions are shallower, relative to the surface, than the body portion.

2. The method of claim 1 further comprising forming a first and a second structure prior to the implanting step for slowing implanting ions that form the first and the second end portions.

3. The method of claim 2 wherein the step of forming the first and the second structures comprises forming the first and the second structures overlying a region of the semiconductor layer where the first and the second end portions are to be formed.

4. The method of claim 2 wherein a region of maximum dopant density of the subcollector is shifted toward the surface by a distance about equal to a height of the first and the second structures above the surface.

5. The method of claim 1 further comprising forming spaced-apart first and second isolation structures in an upper region of the semiconductor layer, forming third and fourth structures overlying the respective first and second isolation structures, wherein the third and the fourth structures slow implanting ions that form the first and the second end portions.

6. The method of claim 1 further comprising:
forming a third collector region overlying the subcollector;
forming a base in contact with the third collector region;
forming an emitter in contact with the base; and
forming spaced-apart first and second isolation sinkers each overlapping an end region of the buried isolation region, the first and the second isolation sinkers and the buried isolation region cooperating to form an isolation tub for the bipolar junction transistor.

7. The method of claim 1 wherein a capacitance between the subcollector and a region of the semiconductor layer thereunder decreases as a distance between an upper surface of the buried isolation region and a lower surface of the first and the second end portions increases.

8. The method of claim 1 wherein the bipolar junction transistor comprises a PNP bipolar junction transistor and the semiconductor layer comprises a p-type semiconductor layer or the bipolar junction transistor comprises an NPN bipolar junction transistor and the semiconductor layer comprises an n-type semiconductor layer.

9. The method of claim 1 further comprising forming a first and a second structure prior to the step of implanting the subcollector to form the first and the second end portions, wherein the step of forming the base further comprises implanting the base, and wherein during the step of implanting the base the first and the second structures limit a lateral extent of the base by slowing implanting ions forming the base.

10. A method for forming a bipolar junction transistor and a metal oxide semiconductor field effect transistor in a semiconductor layer, comprising:
providing the semiconductor layer having a surface;
forming MOSFET structures in a MOSFET region of the semiconductor layer;
forming a first gate stack in the MOSFET region and second and third gate stacks in a bipolar junction transistor region;
forming spaced-apart first and second collector regions in the bipolar junction transistor region;
forming a buried isolation region below a lower surface of each of the first and the second collector regions and extending between the first and the second collector regions; and
implanting a subcollector through the second and the third gate stacks and a region of the semiconductor layer therebetween, wherein the subcollector comprises a body portion and first and second end portions extending therefrom, the first and second end portions overlapping the respective first and second collector regions, and wherein the first and second end portions are shallower, relative to the surface, than the body portion.

11. The method of claim 10 further comprising forming spaced-apart first and second isolation structures in an upper region of the semiconductor layer, wherein the step of forming the first, second and third gate stacks further comprises forming the second and the third gate stacks overlying the respective first and second isolation structures, and wherein the second and third gate stacks slow implanting ions that form the first and the second end portions.

12. The method of claim 10 further comprising:
forming a third collector region overlying the subcollector;
forming a base in contact with the third collector region;
forming an emitter in contact with the base; and
forming spaced-apart first and second isolation sinkers each overlapping an end region of the buried isolation region, the first and the second isolation sinkers and the buried isolation region cooperating to form an isolation tub for the bipolar junction transistor.

13. The method of claim 10 wherein capacitance between the subcollector and a region of the semiconductor layer and the buried isolation region decreases as the distance between the upper surface of the buried isolation region and the lower surface of the first and the second end portions increases.

14. A bipolar junction transistor comprising:
a semiconductor substrate having a surface;
spaced apart first and second collector regions in the substrate; and
a third collector region having a body portion and first and second end portions extending therefrom, the first and second end portions overlapping the respective first and second collector regions, wherein the first and second end portions are shallower relative to the surface than the body portion.

15. The bipolar junction transistor of claim 14 further comprising first and second structures overlying tie surface and substantially vertically aligned with the first and the second end portions of the third collector region.

16. The bipolar junction transistor of claim 14 further comprising first and second isolation structures overlapping end regions of a third isolation structure formed in the substrate, wherein the first, second and third isolation structures comprises an isolation tub for the bipolar junction transistor.

17. The bipolar junction transistor of claim 14 comprising a PNP bipolar junction transistor formed in a p-type substrate or an NPN bipolar junction transistor formed in an n-type substrate.

18. The bipolar junction transistor of claim 14 further comprising a base in conductive communication with the third collector region and an emitter in contact with the base.

19. A BiCMOS circuit comprising:
a semiconductor substrate having a surface;
in a MOSFET region of the substrate:
a doped tub;
a source and a drain in the doped tub;
a first gate stack overlying the doped tub intermediate the source and the drain;
in a BJT region of the substrate:
spaced apart first and second isolation structures in the surface;
second and third gate stacks overlying the respective first and second isolation structures;
spaced apart first and second collector structures;
a subcollector having a body portion and first and second end portions extending therefrom, the first and second end portions overlapping the respective first and second collector structures;
a third collector structure overlying the subcollector;
a base in contact with the third collector structure;
an emitter in contact with the base; and
an isolation structure bounding the first, second and third collector structures and the subcollector, the isolation structure comprising a buried isolation structure below a lower surface of the first and the second collector structures and below a lower surface of the subcollector, and wherein the end portions are shallower relative to the surface than the body portion.

20. The BiCMOS circuit of claim 19 comprising a PNP bipolar junction transistor formed in a p-type substrate or an NPN bipolar junction transistor formed in an n-type tub formed in a p-type substrate.
